(19) United States
(12) Patent Application Publication
(10) Pub. No.: US 2010/0206602 A1
(43) Pub. Date: Aug. 19, 2010

(54) Bump Structure With Multiple Layers And Method Of Manufacture

(75) Inventors: Sang Chul Lee, Seoul (KR); Sung-Wook Kim, Seoul (KR)

Correspondence Address: DR. MARK M. FRIEDMAN;C/O BILL POLKINGHORN - DISCOVERY DISPATCH, 9003 FLORIN WAY, UPPER MARLBORO, MD, 20772, US

(73) Assignee: BARUN ELECTRONICS CO., LTD., Gyeonngi-do (KR)

(21) Appl. No.: 12/738,635

(22) PCT Filed: Oct. 17, 2008
(86) PCT No.: PCT/KR08/06149

§ 371 Date: Apr. 18, 2010

(30) Foreign Application Priority Data
Oct. 19, 2007 (KR) 10-2007-0105661

(51) Int. Cl. H05K 5/06; H05K 3/00

(52) U.S. Cl. 174/50.54; 156/60

(57) ABSTRACT

A bump structure with multiple layers may include a first layer electrically connected to a protective substrate hermetically packaging a base substrate, the first layer allowing the base substrate and the protective substrate to be spaced apart from each other at a predetermined distance; and a second layer electrically connected to the first layer, the second layer being eutectically bonded on a surface of the base substrate. The first layer may have a melting point higher than a eutectic temperature of the second layer and the base substrate. When using a bump structure with multiple layers, it is possible to secure a space in which a micro-structure such as a microelectromechanical systems (MEMS) device on a base substrate may be driven. Further, it is possible to prevent a contact between adjacent structures or electrodes from being generated due to diffusion of a bonding material in a hermetical packaging process.

### TECHNICAL FIELD

Exemplary embodiments relate to a bump structure with multiple layers for wafer-level hermetic packaging and a method of manufacturing the same. More particularly, exemplary embodiments relate to a bump structure with multiple layers, which is electrically connected between a base substrate and a protective substrate to serve as a stopper and as a spacer, and eutectically bonded to the base substrate for hermetically packaging the protective substrate and the base substrate having a micro-structure such as a microelectromechanical systems (MEMS) device or a semiconductor chip, and a method of manufacturing the bump structure.

### BACKGROUND ART

Recently, microelectromechanical systems (MEMS) technique has been introduced as an innovative system minimization technique which will lead the electronic device and semiconductor technique fields in the future. The MEMS technique is a technique in which a specific portion of a system is integrated and formed in a complicated shape of micrometer order using a silicon process on a substrate such as a silicon substrate. The MEMS technique is based on semiconductor device manufacturing techniques including a thin-film deposition technique, an etching technique, a photolithography technique, an impurity diffusion and injection technique, and the like.

Devices manufactured using the MEMS technique are sensitive to external environments including temperature, moisture, fine particles, vibration, impact and the like. As a result, the devices may not operate properly, or errors may frequently occur during operations. Accordingly, it is required to allow a MEMS device to be protected from external environment by forming a protective substrate above a base substrate on which the MEMS device is positioned, to form a hermetically packaged MEMS package.

When forming the aforementioned MEMS package, a predetermined space is necessary so that a MEMS device such as an acceleration sensor may be driven normally. Here, the space is required for a micro-structure such as a sensing electrode of the acceleration sensor to be driven. Therefore, it is necessary to maintain a pre-determined spacing distance between a protective substrate and a base substrate on which a MEMS device is formed so that the MEMS device can be driven in the structure. substrate through a bump structure made of a solder material or metal material, and hermetically packaged by the protective substrate. However, when the base substrate is bonded with the protective substrate using a bump structure made of a single material, an upper surface of the bump structure is diffused horizontally due to local fusing, and therefore, deformation of bump structure may occur easily. Such a deformed bump structure may lead to another bump structure adjacent thereto, or penetrated into or contacted with structures and interconnections formed on a substrate. Therefore, electrical failures may occur.

### DISCLOSURE OF INVENTION

### Technical Problem

Accordingly, there are provided a bump structure with multiple layers for hermetic packaging, which provides a space for driving a micro-structure such as a MEMS device formed on a surface of a base substrate and prevents a contact between adjacent structures or electrodes from being generated due to diffusion of a bonding material in combination with the base substrate and a protective substrate, and a method of manufacturing the bump structure.

### TECHNICAL SOLUTION

An exemplary embodiment provides a bump structure with multiple layers, which includes a first layer electrically connected to a protective substrate hermetically packaging a base substrate, the first layer allowing the base substrate and the protective substrate to be spaced apart from each other at a predetermined distance; and a second layer electrically connected to the first layer, the second layer being eutectically bonded on a surface of the base substrate.

Another exemplary embodiment provides a hermetically packaged structure, which includes a base substrate having a micro-structure formed on a surface thereof; a protective substrate hermetically packaging the base substrate; a first layer electrically connected to a bottom surface of the protective substrate, the first layer allowing the base substrate and the protective substrate to be spaced apart from each other at a pre-determined distance so that the micro-structure formed on the base substrate is driven; and a second layer electrically connected to the first layer, the second layer being eutectically bonded on a surface of the base substrate.

Another exemplary embodiment provides a method of manufacturing a bump structure with multiple layers, which includes forming a first layer on a protective substrate hermetically packaging a base substrate, the first layer allowing the base substrate and the protective substrate to be spaced apart from each other at a pre-determined distance; forming a second layer on the first layer for eutectic bonding to the base substrate; and eutectically bonding the second layer and the base substrate.

According to exemplary embodiments, the first layer may have a melting point higher than a eutectic temperature of the second layer and the base substrate.

### ADVANTAGEOUS EFFECTS

When using a bump structure with multiple layers, it is possible to secure a space in which a micro-structure such as a MEMS device formed on a surface of a base substrate may be driven. Further, it is possible to prevent a contact between adjacent structures or electrodes from being generated due to diffusion of a bonding material in a hermetical packaging process.

### BRIEF DESCRIPTION OF THE DRAWINGS

Description will now be made in detail with reference to certain example embodiments illustrated in the accompanying drawings which are given hereinbelow by way of illustration only, and thus are not limitative of the example embodiments disclosed herein, and wherein:

FIG. 1 is a perspective view of a structure hermetically packaged using a bump structure according to an exemplary embodiment;

FIG. 2 is a perspective view showing a section of the hermetically packaged structure, taken along line A-A′ of FIG. 1;

FIG. 3 is a partial enlarged sectional view of a portion of the section shown in FIG. 2;

FIG. 4 is a sectional view showing a section of a bump structure according to another exemplary embodiment;

FIG. 5 is a sectional view of a base substrate and a protective substrate;

FIG. 6 is a sectional view of the base substrate and the protective substrate after a silicon layer is formed;

FIG. 7 is a sectional view of the base substrate and the protective substrate after a first layer is formed;

FIG. 8 is a sectional view of the base substrate and the protective substrate after a first layer is formed; and

FIG. 9 is a sectional view of the base substrate and the protective substrate after a diffusion barrier layer is formed.

It should be understood that the appended drawings are not necessarily to scale, presenting a somewhat simplified representation. The specific design features as disclosed herein, including, for example, specific dimensions, orientations, locations, and shapes will be determined in part by the particular intended application and use environment.

In the figures, reference numbers refer to the same or equivalent parts thought the figures of the drawing.

### MODE FOR THE INVENTION

Hereinafter, reference will now be made in detail to various embodiments disclosed herein, examples of which are illustrated in the accompanying drawings and described below. While the embodiments disclosed herein will be described in conjunction with example embodiments, it will be understood that the present description is not intended to be limitative. On the contrary, the embodiments disclosed herein are intended to cover not only the example embodiments, but also various alternatives, modifications, equivalents and other embodiments, which may be included within the spirit and scope as defined by the appended claims.

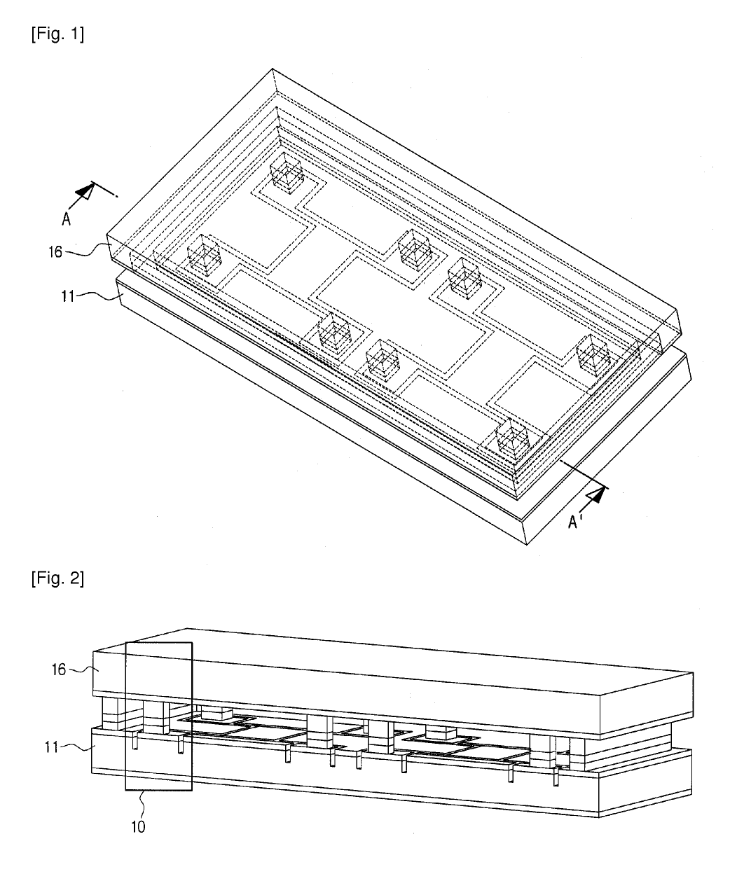

FIG. 1 is a perspective view of a structure hermetically packaged using a bump structure according to an exemplary embodiment disclosed herein.

As shown in FIG. 1, a base substrate 11 is positioned at a lower portion of the hermetically packaged bump structure. The base substrate 11 may include various types of substrates such as a printed circuit board (PCB) and a semiconductor substrate. The base substrate 11 may be made of silicon (Si). A protective substrate 16 is positioned above the base substrate 11. The base substrate 11 is covered and hermetically packaged by the protective substrate 16. The base substrate 11 and the protective substrate 16 are electrically connected to each other through the bump structure according to an exemplary embodiment, which will be described later.

FIG. 2 is a perspective view showing a section of the hermetically packaged structure, taken along line A-A′ of FIG. 1. A region 10 at which a bump structure is positioned in the hermetically packaged structure according to an exemplary embodiment is shown in FIG. 2. As shown in FIG. 2, the bump structure according to an exemplary embodiment is positioned in a portion of the region between the base substrate 11 and the protective substrate 16 so that the two substrates are electrically connected through the bump structure. The base substrate 11 and the protective substrate 16 are spaced apart from each other at a predetermined distance by the bump structure so as to provide a space in which a micro-structure such as a microelectromechanical systems (MEMS) device formed on a surface of the base substrate 11 may be driven.

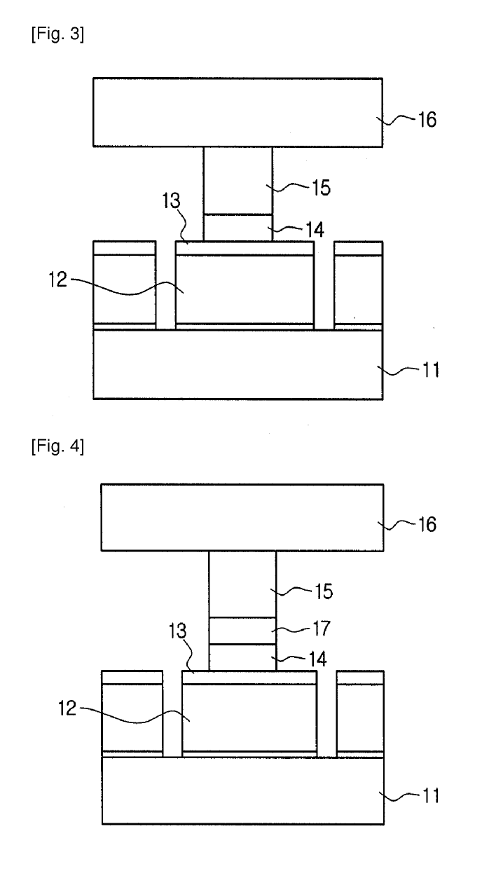

FIG. 3 is a partial enlarged sectional view of the region 10 at which the bump structure according to an exemplary embodiment is positioned in the sectional view shown in FIG. 2. Referring to FIG. 3, the bump structure includes a first layer 15 electrically connected to a bottom surface of the protective substrate 16, and a second layer 14 electrically connected to the first layer 15 and eutectically bonded on the surface of the base substrate 11. The first and second layers 15 and 14 are formed of one or more metals having relatively excellent conductivity.

A micro-structure 12 is formed on the surface of the base substrate 11. In an exemplary embodiment, the micro-structure 12 may be a MEMS device such as an acceleration sensor or an inertia sensor. Alternatively, the micro structure may be a semi-conductor chip. When hermetical packaging is performed using the bump structure according to an exemplary embodiment, the base substrate 11 is eutectically bonded to the second layer 14 of the bump structure. The eutectic bonding refers to a bonding method in which a bonding layer is formed by heat pressing metals heated up to a eutectic temperature and then solidifying the metals at a temperature lower than the eutectic temperature. For the eutectic bonding, the base substrate 11 may be made of silicon (Si). When the base substrate 11 is not made of silicon, the bump structure may further include a silicon layer 13 formed on the surface of the base substrate 11 and eutectically bonded to the second layer 14.

The base substrate 11 is bonded with the protective substrate 16 and hermetically packaged by the protective substrate 16. The protective substrate 16 is a substrate that shields the base substrate 11 from external environment. The protective substrate 16 is bonded with the base substrate 11 above the base substrate 11 using the bump structure according to an exemplary embodiment. In this case, the bump structure also serves as a path through which the base substrate 11 and the protective substrate 16 are electrically connected.

The first layer 15 is electrically connected to the bottom surface of the protective substrate 16. The first layer 15 serves as a spacer and a stopper between the base substrate 11 and the protective substrate 16. First, the first layer 15 serves as a spacer that allows the base substrate and the protective substrate 16 to be spaced apart from each other at a predetermined distance, so that a space for driving the micro-structure 12 is formed between the two substrates. A space is required so that a MEMS device such as an acceleration sensor is operated normally. In the space, a micro-electrode for acceleration sensing or the like is moved up and down or left and right, depending on acceleration. Accordingly, when the base substrate 11 is bonded with the protective substrate 16 and hermetically packaged by the protective substrate 16, the base substrate 11 and the protective substrate 16 may be spaced apart from each other by a desired distance by adjusting the height of the first layer 15 depending on the size of a required space.

Further, the first layer 15 serves as a stopper that limits horizontal diffusion of the second layer 14 to the thickness of the second layer 14 in eutectic bonding. In an exemplary embodiment, the first layer 15 has a melting point higher than the eutectic temperature of the second layer 14 and the base substrate 11 or the eutectic temperature of the second layer 14 and the silicon layer 13. In this case, the first layer 15 is not melted during eutectic bonding of the second layer 14 and silicon. Therefore, it is possible to prevent the physical shape of the first layer 15 from being deformed due to the eutectic bonding. Accordingly, the shape of the bump structure can be maintained firmly.

For example, when the second layer 14 is made of gold (Au) and the base substrate 11 is made of silicon (Si), a eutectic reaction of Au—Si is generated at a contact surface between the second layer 14 and the base substrate 11. Therefore, the first layer 15 may be made of a material having a melting point higher than 363° C., which is a eutectic temperature of Au—Si. In an exemplary embodiment, the first layer 15 may include any one selected from the group consisting of copper, copper alloy, titanium, titanium alloy, chromium, chromium alloy, nickel, nickel alloy, gold, gold alloy, aluminum, aluminum alloy, vanadium and vanadium alloy, but not limited thereto. That is, the first layer 15 may be made of various kinds of metal.

Due to the first layer 15, it is possible to prevent the bump structure from being excessively diffused horizontally during eutectic bonding. Accordingly, it is possible to prevent the bump structure from being electrically connected to an adjacent structure or another bump structure on the base substrate 11. Further, since the first layer 15 is connected to the second layer 14 to form a bump structure, the thickness of the second layer 14 may be decreased more than when the bump structure is formed only with the second layer 14. When the second layer 14 is made of a high-priced metal such as gold (Au), most of the bump structure may be formed with the first layer 15 such that the first layer 15 has a greater thickness than that of the second layer 14. Thus, the second layer 14 may be formed to a minimum thickness necessary for eutectic bonding, thereby saving cost of a material used in forming the bump structure.

The second layer 14 for eutectic bonding to the base substrate 11 is electrically connected to the bottom surface of the first layer 15. In an exemplary embodiment, the second layer 14 may be made of gold (Au) and the base substrate 11 may be made of silicon (Si). The base substrate 11 and the second layer 14 are eutectically bonded to each other through Au-Si eutectic bonding. The second layer 14 is diffused horizontally through the eutectic bonding. Therefore, the area of a contact interface between the second layer 14 and the base substrate 11 is increased.

In the exemplary embodiment shown in FIG. 3, the second layer 14 is eutectically bonded to a top of the micro-structure 12 formed on the surface of the base substrate 11, which is provided for illustrative purposes. Alternatively, the second layer 14 may be eutectically bonded to a region in which the micro-structure 12 is not formed on the base substrate 11.

As described above, a bump structure with two layers, i.e., first and second layers, has been described in the embodiment shown in FIG. 3. On the other hand, FIG. 4 shows a bump structure with three layers, unlike the exemplary embodiment shown in FIG. 3.

Referring to FIG. 4, a diffusion barrier layer 17 is further formed between a first layer 15 and a second layer 14. The diffusion barrier layer 17 is a layer that prevents a material constituting the second layer 14 from being diffused into the first layer 15 due to melting of the second layer in eutectic bonding. The diffusion barrier layer 17 may be made of a material used for a diffusion barrier layer or bonding layer, including nickel, titanium, chromium, copper, vanadium, aluminum, gold, cobalt, manganese, palladium or an alloy thereof. Alternatively, one or more layers may constitute the diffusion barrier layer 17.

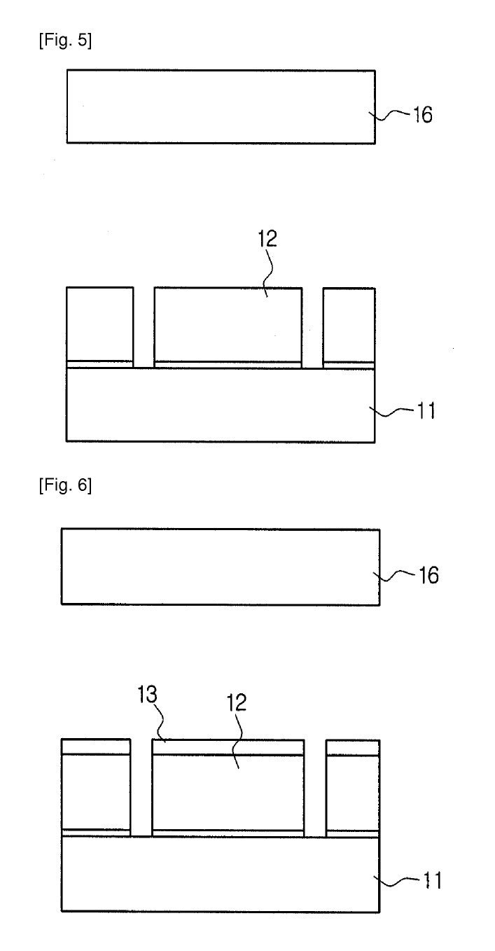

FIGS. 5 to 9 are sectional views illustrating a method of manufacturing a bump structure with multiple layers according to an exemplary embodiment. First, a base substrate 11 and a protective substrate 16 are shown in FIG. 5. Here, a bump structure is not formed between the base substrate 11 and the protective substrate 16 yet. When the base substrate is not made of silicon (Si), a silicon layer 13 for eutectic bonding is formed on the base substrate 11 as shown in FIG. 6. As will be described later, the silicon layer 13, the first and second layers 15 and 14 and the diffusion barrier layer 17 may be formed through deposition, plating or other various processes.

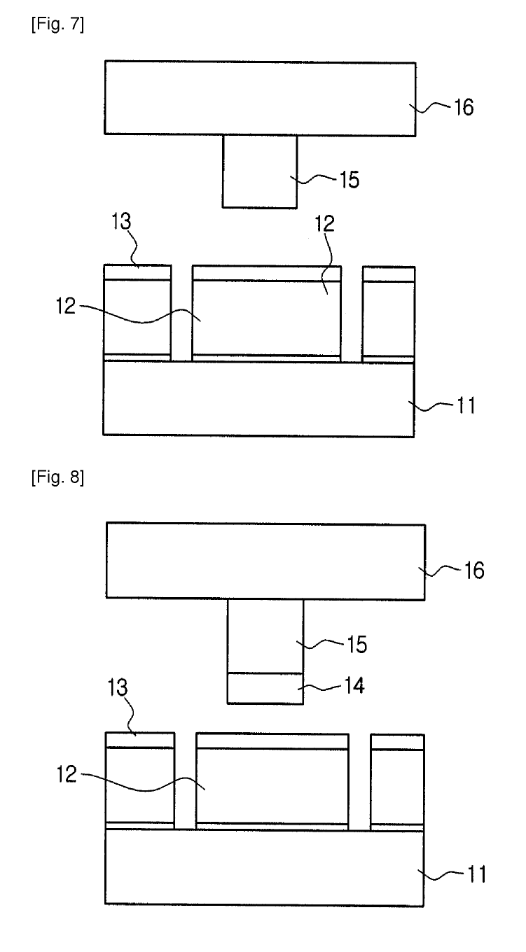

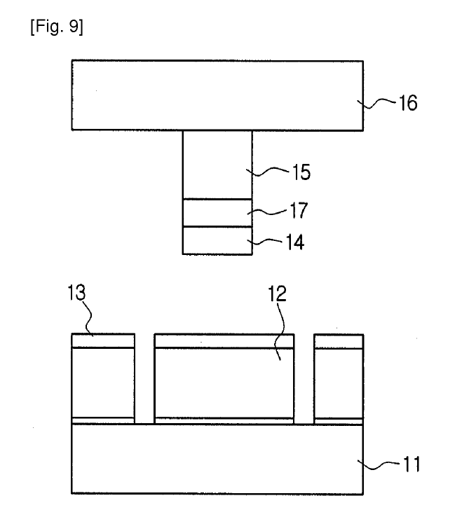

Subsequently, as shown in FIG. 7, the first layer 15 is formed on a portion of the protective substrate 16. Here, the first layer serves as a spacer and a stopper. At this time, the first layer 15 is formed to a sufficient thickness so as to secure a spacing distance at which a micro-structure 12 formed on a surface of the base substrate 11 may be sufficiently driven. Subsequently, as shown in FIG. 8, the second layer 14 is formed on the first layer 15 formed on the protective substrate 16, thereby forming a bump structure. In an exemplary embodiment, a diffusion barrier layer 17 may be formed on the first layer 15 before the second layer 14 is formed, as shown in FIG. 9. Here, the diffusion barrier layer 17 prevents diffusion between the first and second layers 15 and 14.

Once the diffusion barrier layer 17 is formed, the base substrate 11 and the protective substrate 16 are bonded to each other through eutectic bonding. For the eutectic bonding, the base substrate 11 and the protective substrate 16 are first adhered to each other by applying pressure to the substrates 11 and 16. Then, the second layer 14 of the bump structure and the base substrate 11 are heated up to a eutectic temperature of the second layer 14 material and the base substrate 11 material. For example, when the second layer 14 is made of gold (Au) and the base substrate 11 is made of silicon (Si), the eutectic temperature of Au—Si is 363° C. The bump structure and the base substrate 11 are eutectically bonded to each other by heat, thereby forming the bump structure described with reference to FIGS. 3 and 4.

As described above, the bump structure according to exemplary embodiments may be applied to various types of devices including a MEMS package and a semi-conductor package. Particularly, the bump structure according to exemplary embodiments may be effectively applied to Au—Si eutectic bonding. The Au—Si eutectic bonding may be widely applied to wafer level vacuum packaging MEMS devices which are driven using vibration. Further, the bump structure according to exemplary embodiments may be applied to various types of devices including silicon wafer devices having metal interconnections and electronic devices having two-dimensional or three-dimensional structures made of various kinds of metals including silicon, in addition to the MEMS devices.

### INDUSTRIAL APPLICABILITY

Exemplary embodiments relate to a bump structure with multiple layers for wafer-level hermetic packaging and a method of manufacturing the same. More particularly, exemplary embodiments relate to a bump structure with multiple layers, which is electrically connected between a base substrate and a protective substrate to serve as a stopper as a spacer, and eutectically bonded to the base substrate for hermetically packaging the protective substrate and the base substrate having a micro-structure such as a microelectromechanical systems (MEMS) device or a semiconductor chip, and a method of manufacturing the bump structure.

1. A bump structure with multiple layers, comprising:
a first layer electrically connected to a protective substrate hermetically packaging a base substrate, the first layer allowing the base substrate and the protective substrate to be spaced apart from each other at a predetermined distance; and
a second layer electrically connected to the first layer, the second layer being eutectically bonded on a surface of the base substrate,
wherein the first layer has a melting point higher than a eutectic temperature of the second layer and the base substrate.

2. The bump structure according to claim 1, wherein the first layer has a greater thickness than that of the second layer.

3. The bump structure according to claim 1, further comprising a diffusion barrier layer formed between the first and second layers, the diffusion barrier layer preventing a material constituting the second layer from being diffused into the first layer in the eutectic bonding of the second layer and the base substrate.

4. The bump structure according to claim 3, wherein the diffusion barrier layer comprises at least one material selected from the group consisting of nickel, titanium, chromium, copper, vanadium, aluminum, gold, cobalt, manganese, palladium or an alloy thereof.

5. The bump structure according to claim 1, wherein the second layer is made of gold (Au).

6. A hermetically packaged structure comprising:
a base substrate having a micro-structure formed on a surface thereof;
a protective substrate hermetically packaging the base substrate;
a first layer electrically connected to a bottom surface of the protective substrate, the first layer allowing the base substrate and the protective substrate to be spaced apart from each other at a predetermined distance so that the micro-structure formed on the base substrate may be driven; and
a second layer electrically connected to the first layer, the second layer being eutectically bonded on a surface of the base substrate,
wherein the first layer has a melting point higher than a eutectic temperature of the second layer and the base substrate.

7. The hermetically packaged structure according to claim 6, wherein the first layer has a greater thickness than that of the second layer.

8. The hermetically packaged structure according to claim 6, further comprising a diffusion barrier layer formed between the first and second layers, the diffusion barrier layer preventing a material constituting the second layer from being diffused into the first layer in the eutectic bonding of the second layer and the base substrate.

9. The hermetically packaged structure according to claim 8, wherein the diffusion barrier layer comprises at least one material selected from the group consisting of nickel, titanium, chromium, copper, vanadium, aluminum, gold, cobalt, manganese, palladium or an alloy thereof.

10. The hermetically packaged structure according to claim 6, wherein the second layer is made of gold (Au), and the base substrate is made of silicon (Si).

11. The hermetically packaged structure according to claim 6, wherein the second layer is made of gold (Au), and the base substrate comprises a silicon layer formed on the surface of the base substrate and eutectically bonded to the second layer.

12. The hermetically packaged structure according to claim 6, wherein the micro-structure is a microelectromechanical systems (MEMS) device.

13. A method of manufacturing a bump structure with multiple layers, the method comprising:
forming a first layer on a protective substrate hermetically packaging a base substrate, the first layer allowing the base substrate and the protective substrate to be spaced apart from each other at a predetermined distance;
forming a second layer on the first layer for eutectic bonding to the base substrate; and
eutectically bonding the second layer and the base substrate,
wherein the first layer has a melting point higher than a eutectic temperature of the second layer and the base substrate.

14. The method according to claim 13, wherein the eutectically bonding comprises:
applying a predetermined pressure so that the base substrate and the second layer are adhered close to each other; and
heating the base substrate and the second layer at a predetermined temperature.

15. The method according to claim 13, further comprising forming a silicon layer on the base substrate prior to forming the first layer.

16. The method according to claim 13, further comprising forming a diffusion barrier layer on the first layer, the diffusion layer preventing a material constituting the second layer from being diffused into the first layer in the eutectic bonding, prior to forming the second layer.

17. The method according to claim 16, wherein the diffusion barrier layer comprises at least one material selected from the group consisting of nickel, titanium, chromium, copper, vanadium, aluminum, gold, cobalt, manganese, palladium or an alloy thereof.

18. The method according to claim 13, wherein the first layer is made of gold (Au).

19. The method according to claim 13, wherein the first layer has a greater thickness than that of the second layer.
